(19) United States
(12) Patent Application Publication
(10) Pub. No.: US 2014/0374241 A1
(43) Pub. Date: Dec. 25, 2014

(54) METHOD FOR DEPOSITING A LIPON COATING ON A SUBSTRATE

(71) Applicant: Fraunhofer-Gesellschaft zur Förderung der angewandten Forschung e.V., Munich (DE)

(72) Inventors: Steffen Günther, Dresden (DE); Matthias Fahland, Dresden (DE); Henry Morgner, Dresden (DE); Steffen Straach, Dresden (DE); Björn Meyer, Dresden (DE)

(21) Appl. No.: 14/377,120

(22) PCT Filed: Jan. 16, 2013
(86) PCT No.: PCT/EP2013/050720

§ 371 Date: Aug. 6, 2014

(30) Foreign Application Priority Data
Feb. 27, 2012 (DE) 10 2012 003 594.2

(51) Int. Cl. C23C 14/00; C23C 14/06

(52) U.S. Cl. CPC C23C 14/0036; C23C 14/0641
USPC 204/192.15

(57) ABSTRACT

A method for depositing a LiPON coating on a substrate is provided, wherein the vaporization material, which is located in a vessel and which includes at least the chemical elements lithium, phosphorus and oxygen, is vaporized within a vacuum chamber. Here the vaporization material is heated by means of a thermal vaporization apparatus, and simultaneously either a nitrogen-containing component is introduced into the vacuum chamber or a nitrogen-containing material is co-vaporized, and wherein the vapor particle mist rising from the vessel is permeated by a plasma before the deposition on the substrate.

This application is a national stage entry of International Patent Application PCT/EP2013/050720, filed Jan. 16, 2013, entitled “VERFAHREN ZUM ABSCHEIDEN EINER LIPON-SCHICHT AUF EINEM SUBSTRAT,” the entire contents of which are incorporated by reference, which in turn claims priority to German patent application 10 2012 003 594.2, filed Feb. 27, 2012, entitled “Verfahren zum Abscheiden einer LiPON-Schicht auf einem Substrat”, the entire contents of which are incorporated by reference.

### BACKGROUND

The invention relates to a method for depositing a lithium phosphorous oxynitride coating (LiPON coating) on a substrate by physical vapor deposition.

### BRIEF DESCRIPTION OF THE DRAWINGS

FIG. 1 shows a diagrammatic representation of a device for carrying out the method according to the invention.

### DESCRIPTION

LiPON is suitable as a solid electrolyte for batteries and accumulators due to its ion conductivity and simultaneous electron nonconductivity. In a typical coating system used for this purpose, LiPON coatings having a coating thickness of approximately 1 μm to 1.5 μm are needed. It is known to deposit such LiPON coatings by RF sputtering (WO 99/57770 A1). However, such methods are characterized by a low coating rate and thus by a low productivity, which leads to relatively expensive products.

Moreover, it is known that it is also possible to deposit LiPON coatings by electron beam coating methods. Here, lithium phosphate (LiPO) is vaporized by means of an electron beam that acts directly on the vaporization material within a nitrogen-containing reactive gas atmosphere. The disadvantage here is the cost intensive and complicated electron beam technology. Although the coating rate can be increased thereby in comparison to RF sputtering, it also results in a high product price due to the cost-intensive apparatus technology. An additional disadvantage of this method is that the direct vaporization of material by means of an electron beam leads to formation of splatters which are deposited on the substrate to be coated and thus have a negative influence on the coating quality.

The invention is therefore based on the technical problem of providing a method for depositing a LiPON coating, by means of which the disadvantages of the prior art can be overcome. In particular, it should be possible, by means of the method according to the invention, to deposit a LiPON coating at a high coating rate but reduced cost expenditure in comparison to the prior art.

According to the invention, a LiPON coating is deposited on a substrate, in that a vaporization material, which includes at least the chemical elements lithium, phosphorus and oxygen, is vaporized by means of a thermal vaporization apparatus within a vacuum chamber. The method according to the invention thus also differs from methods wherein a vaporization material is vaporized directly by means of an electron beam. In the method according to the invention, simultaneously with the thermal vaporization of the vaporization material, a nitrogen-containing component, preferably a nitrogen-containing reactive gas, is introduced into the vacuum chamber, and the rising vapor particle mist is permeated by a plasma. As nitrogen-containing reactive gas, it is suitable to use, for example, gases such as ammonia (NH₃), laughing gas (NO₂) or also nitrogen itself. Alternatively to the introduction of a nitrogen-containing reactive gas, it is also possible to introduce, for example, a nitrogen-containing precursor into the vacuum chamber. The method according to the invention is characterized by a known high deposition rate for thermal vaporization and simultaneously by low production costs.

An additional alternative for the introduction of a nitrogen-containing reactive gas into the vacuum chamber can be carried out by co-vaporizing a nitrogen-containing material in the vacuum chamber instead of introducing the nitrogen-containing reactive gas into the vacuum chamber, i.e., the vaporization material, which comprises at least the chemical elements lithium, phosphorus and oxygen, is vaporized in a first vessel and a nitrogen-containing material is vaporized in the same vacuum chamber in a separate second vessel. For example, LiN can be used as nitrogen-containing material that is co-vaporized in a second vessel.

Additional chemical modifications of a deposited LiPON coating can be made by the additional introduction of other reactive gases. In particular, oxygen can be used, to influence the ratio of nitrogen to oxygen in the deposited coating in a targeted manner.

The vaporization of the starting material can be achieved preferably by indirect heating by means of radiant heaters. A direct heating of the vaporization material within current carrying or induction heated nacelles is also advantageous.

In the method according to the invention, it is advantageous to use LiPO as vaporization material, because with this starting material only one additional compound containing nitrogen has to be incorporated to achieve the desired LiPON coating deposition.

Advantageously, the generation of the plasma is carried out by means of hollow-cathode arc discharge, because particularly high plasma densities can be generated thereby. Alternatively, a plasma can also be generated by excitation with microwaves. This has the advantage that the thermal stress on a substance to be coated is reduced. Moreover, plasmas can be generated by inductive coupling in order to further reduce the apparatus costs.

Furthermore, the possibility exists of generating a plasma by means of a corona discharge with superposed magnetic field. Technical systems that are available for this purpose allow a very homogeneous plasma propagation over a large surface extent. The stability of the deposition process can be further improved by using a pulsed plasma, wherein the pulse technology can be used with all the above-mentioned plasma types.

Although, in mentioning the prior art, it has been indicated that direct vaporization of material by means of an electron beam has a negative effect due to the formation of splatters, the method according to the invention can also be implemented with the participation of an electron beam. However, here it is not the vaporization material itself that is heated and vaporized by the action of the electron beam; instead it is possible, for example, to heat a vessel, in which the vaporization material is present, by means of an electron beam. Alternatively, a radiant heater can also be heated by means of an electron beam. However, the disadvantage here is the already-mentioned high costs of the electron beam apparatuses.

An additional alternative for heating the vaporization material in the method according to the invention consists in using generated plasma simultaneously for the vaporization of the starting material.

In an embodiment, a covering is arranged between the vaporization apparatus and the substrate in such a manner in the line of sight that the rising vapor cannot rise in a straight line from the vaporization vessel to the vaporization area on the substrate to be coated, but must first pass by the covering laterally. In this way one prevents splatters from the heated vaporization material from hitting the substrate.

Between the vaporization apparatus and the substrate, a heat shield can be arranged moreover, in order to lower the thermal stress on the substrate.

Additional gases can be fed into the process space in order to further influence the deposition process. This may involve, for example, known process steps for regulating the process pressure. As a result, it is possible to influence the coating homogeneity, porosity and topography.

In addition, the vaporization rate can also be regulated in order to achieve constant coating thicknesses over a long process time frame.

Coatings deposited by the method according to the invention are particularly suitable for use as solid electrolyte coatings for batteries and accumulators.

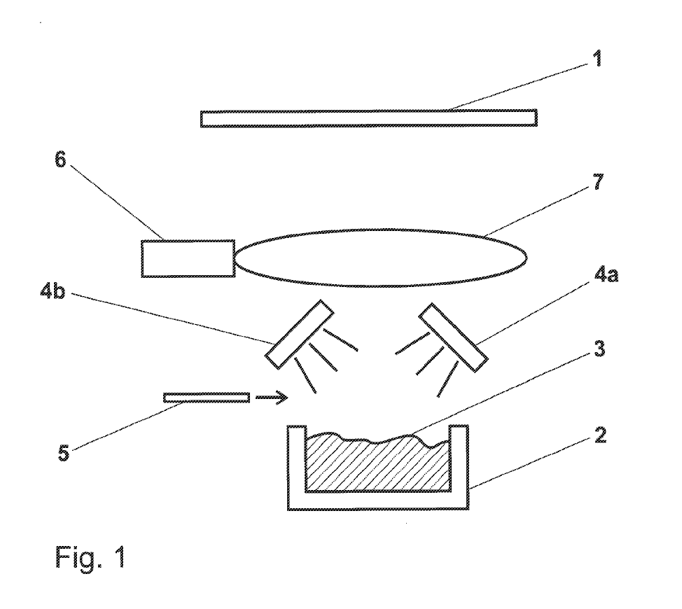

The invention is explained in further detail below in reference to an embodiment example. FIG. 1 shows a diagrammatic representation of a device for carrying out the method according to the invention. In a vacuum chamber not shown in FIG. 1 a LiPON coating is to be deposited on a band-shaped polymer film substrate 1. For this purpose, the substrate 1 is moved at a band speed of 1 m/min through the vacuum chamber. Beneath the substrate 1, a graphite crucible 2 is arranged, in which the LiPO granulate is located as vaporization material 3. Above the graphite crucible 2, two radiant heaters 4a and 4b are arranged so that their emission direction points in the direction of the vaporization material 3. The radiation heaters 4a, 4b are operated at a heat power of 15 kW each, resulting in the heating of the LiPO located in the graphite crucible 2 and finally in its vaporization. Through an inlet 5 arranged between the graphite crucible 2 and the radiation heaters 4a, 4b viewed in the vertical direction, the reactive gas nitrogen is introduced at 1000 sccm into the vacuum chamber. Between the radiation heaters 4a, 4b and the substrate 1, a plasma source 6 designed as a hollow cathode is located, which generates a plasma 7 due to a hollow cathode arc discharge operated at a 150 A discharge current, plasma which permeates the vapor particle mist rising from the vaporization material 3. The LiPO vapor particles are activated by the plasma and excited for the reaction with the nitrogen that is introduced into the vacuum chamber, as a result of which a LiPON coating with a coating thickness of 500 nm is deposited on the underside of the substrate 1.

The coating thickness of the LiPON coating deposited on the substrate 1 can be set, for example, via the band speed and/or the power of the radiation heater, wherein both the lowering of the band speed and the increase of the electrical power of the radiant heater can lead to an increase in the coating thickness.

1. Method for depositing a LiPON coating on a substrate, wherein vaporization material, which is located in a vessel and which includes at least chemical elements lithium, phosphorus and oxygen, is vaporized within a vacuum chamber, wherein the vaporization material is heated by means of at least one thermal vaporization apparatus, and simultaneously either a nitrogen-containing component is introduced into the vacuum chamber or a nitrogen-containing material is co-vaporized, and wherein the vapor particle mist rising from the vessel is permeated by a plasma before the deposition on the substrate.

2. The method of claim 1, wherein at least one radiant heater (4a; 4b) is used as vaporization apparatus.

3. The method of claim 1, wherein at least one vaporizer nacelle heated by current flow is used as vaporization apparatus.

4. The method of claim 1, wherein at least one inductively heated vaporizer nacelle is used as vaporization apparatus.

5. The method of claim 1, wherein LiPO is used as vaporization material.

6. The method of claim 1, wherein a hollow cathode arc discharge is used for generating the plasma.

7. The method of claim 1, wherein a corona discharge with superposed magnetic field is used for generating the plasma.

8. The method of claim 1, wherein microwaves are used for generating the plasma.

9. The method of claim 1, wherein the supply of energy to the device generating the plasma occurs in a pulsed manner.

10. The method of claim 1, wherein a nitrogen-containing reactive gas is introduced into the vacuum chamber, as nitrogen-containing component.

11. The method of claim 10, wherein nitrogen, ammonia or laughing gas is used as reactive gas.
